(19) United States
(12) Patent Application Publication
(10) Pub. No.: US 2014/0070804 A1
(43) Pub. Date: Mar. 13, 2014

(54) MRI METHOD OF FASTER CHANNEL-BY-CHANNEL RECONSTRUCTION WITHOUT IMAGE DEGRADATION

(71) Applicants: Feng Huang, Gainesville, FL (US); Wei Lin, Gainesville, FL (US)

(72) Inventors: Feng Huang, Gainesville, FL (US); Wei Lin, Gainesville, FL (US)

(73) Assignee: KONINKLIJKE PHILIPS N.V., Eindhoven (NL)

(21) Appl. No.: 14/005,300

(22) PCT Filed: Mar. 16, 2012
(86) PCT No.: PCT/IB2012/051265

§ 371 Date: Nov. 26, 2013

Related U.S. Application Data
(60) Provisional application No. 61/453,564, filed on Mar. 17, 2011.

(51) Int. Cl. G01R 33/56; G01R 33/34

(52) U.S. Cl. CPC G01R 33/56; G01R 33/34
USPC 324/309; 324/322

(57) ABSTRACT

A plurality of coil elements (18, 18′) and corresponding receivers (26) define a plurality of channels, each carrying a corresponding partial k-space data set (60, 64). One or more processors (30) generate (80) a first image representation (76) based on the plurality of partial k-space data sets, generate a relative sensitivity map (82) for each of the channels, project (90) the first image representation (76) with each of the relative sensitivity maps (82) to generate a plurality of recreated k-space data sets (92), and each partial k-space data and the corresponding recreated k-space data set are combined to generate substituted k-space data sets (96). The substituted k-space data sets are reconstructed (100) into a plurality of images (102) which are combined (104) to create a final image (106).

The present application relates to magnetic resonance arts. It finds particular application in channel-by-channel reconstruction algorithms employed in parallel imaging methods.

The introduction of multi-coil arrays in magnetic resonance (MR) systems to improve the signal-to-noise ratio (SNR) over volume coils and large surface coils has led to the introduction of multiple channel receivers included in the systems. More recently, the success of partially parallel imaging (PPI) techniques is driving the industry to develop MRI systems with a greater number of receiver channels to enable parallel imaging with higher acceleration factors and broader coverage. These techniques use spatial information contained in the component coils of an array to partially replace spatial encoding which would normally be performed using gradients, thereby greatly reducing imaging time.

Commercial MRI systems with 32 or more receiver channels are becoming popular for regular clinical use. With the increase of the number of channels, the computation time required for reconstruction has greatly increased. For reconstruction algorithms using single channel information, such as partial Fourier and k-t FOCUSS, the reconstruction times increase linearly with channel count. For channel-by-channel PPI reconstruction techniques, such as Generalized Auto-calibrating Partially Parallel Acquisitions (GRAPPA) and Data Convolution and Combination Operation (COCOA), the reconstruction time increases quadratically. Thus reconstruction with a 32-channel coil may take 16 times longer than an 8-channel coil which renders real-time and high-throughput imaging difficult.

To reduce reconstruction time without significantly degrading the final image quality, two different sets of channel reduction techniques have been proposed. One set of techniques, channel compression, reduces reconstruction time by first linearly combining the original channels using principle component analysis (PCA) into a lesser number of channels. Of those combined channels, the ones with the largest eigenvalues are used for reconstruction. The degree of channel compression is limited by the need to avoid significant signal loss. For example, to if the number of compressed channels is fewer than 12 for a 32 channel cardiac coil, image quality is sacrificed.

The other set of techniques reconstruct only one virtual composite channel using all original channels. This set of techniques includes direct virtual coil (DVC) reconstruction and synthetic target (ST) reconstruction. Because only one virtual channel is reconstructed, the reconstruction time can be greatly reduced. However, these techniques, DVC and ST, suffer from lack of a technique to efficiently optimize the phase definition to produce an optimal calibration signal. Without an accurate calibration signal, the final reconstruction can be significantly compromised or even damaged.

The present application provides a new and improved method and system which overcomes the above-referenced problems and others.

In accordance with one aspect, a method of magnetic resonance imaging is provided. A first image representation of an examination region is generated based on a plurality of partial k-space data sets. Each data is associated with at least one channel. A relative sensitivity map is generated for each of a plurality of coil elements, each coil element being associated with at least one channel. The first image representation and each relative sensitivity map are projected to generate a plurality of recreated k-space data sets. Each recreated k-space data set corresponds to one of the partial k-space data sets. Each of the partial k-space data sets is combined with the corresponding recreated k-space data set to generate substituted k-space data sets.

In accordance with another aspect, a computer-readable medium carries software for controlling one or more processors to perform the method of the preceding paragraph.

In accordance with another aspect, a magnetic resonance imaging system includes a plurality of coil elements and corresponding receivers which define a plurality of channels. Data from the channels generated during a magnetic resonance imaging sequence constitute a plurality of partial k-space data sets. One or more processors are programmed to generate a first image representation of an examination region based on the plurality of partial k-space data sets. A relative sensitivity map is generated for each of the channels. The first image representation with each of the relative sensitivity maps is projected to generate a corresponding plurality of recreated k-space data sets. Each partial k-space data set and the corresponding recreated k-space data set are combined to generate substituted k-space data sets.

In accordance with another aspect, an image reconstruction system which generates a plurality of original channels of partial k-space data includes one or more processors. The one or more processors are programmed to compress the plurality of original channels of k-space data into a fewer number of compressed channels. A channel-by-channel reconstruction algorithm is applied to the partial k-space data of one or more of the compressed channels to generate a virtual coil image. A relative sensitivity map is calculated for each of the original or compressed channels. The virtual composite image coil is projected using the relative sensitivity maps to generate a recreated sensitivity map corresponding to each original or compressed channel. Acquired data from the partial k-space data of each of the original or compressed channels is inserted into each of the corresponding recreated k-space data sets to generate substituted k-space data sets. The recreated k-space data sets are reconstructed and combined to produce a final image.

One advantage resides in that reconstruction time is reduced.

Another advantage resides in that image degradation in partially parallel imaging techniques is reduced.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

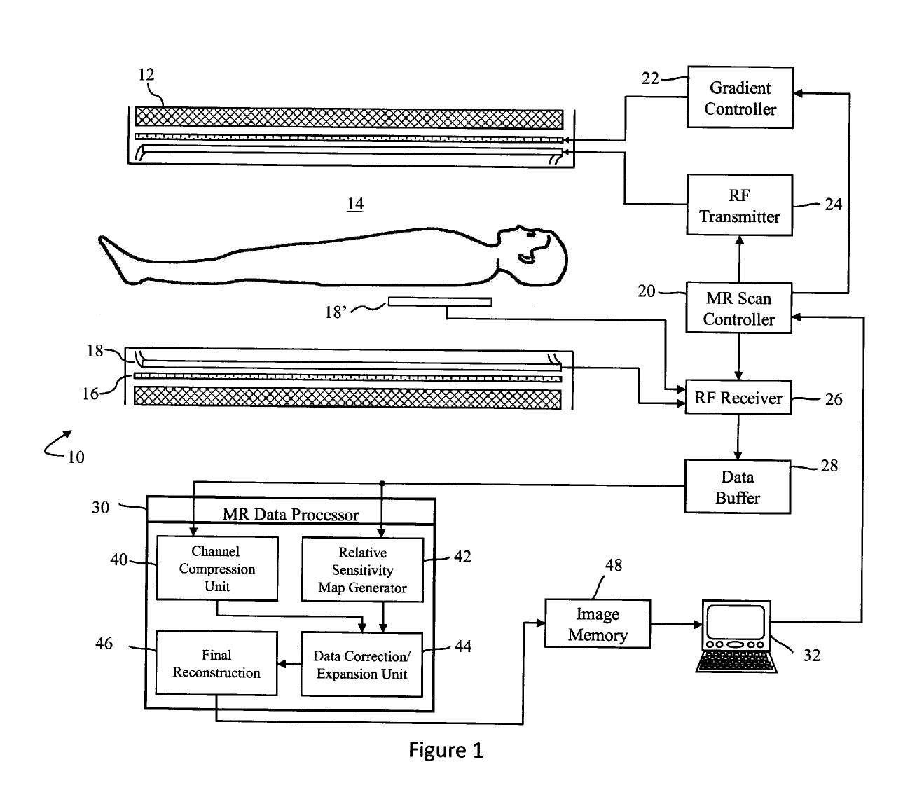

FIG. 1 is a diagrammatic illustration of a magnetic resonance system;

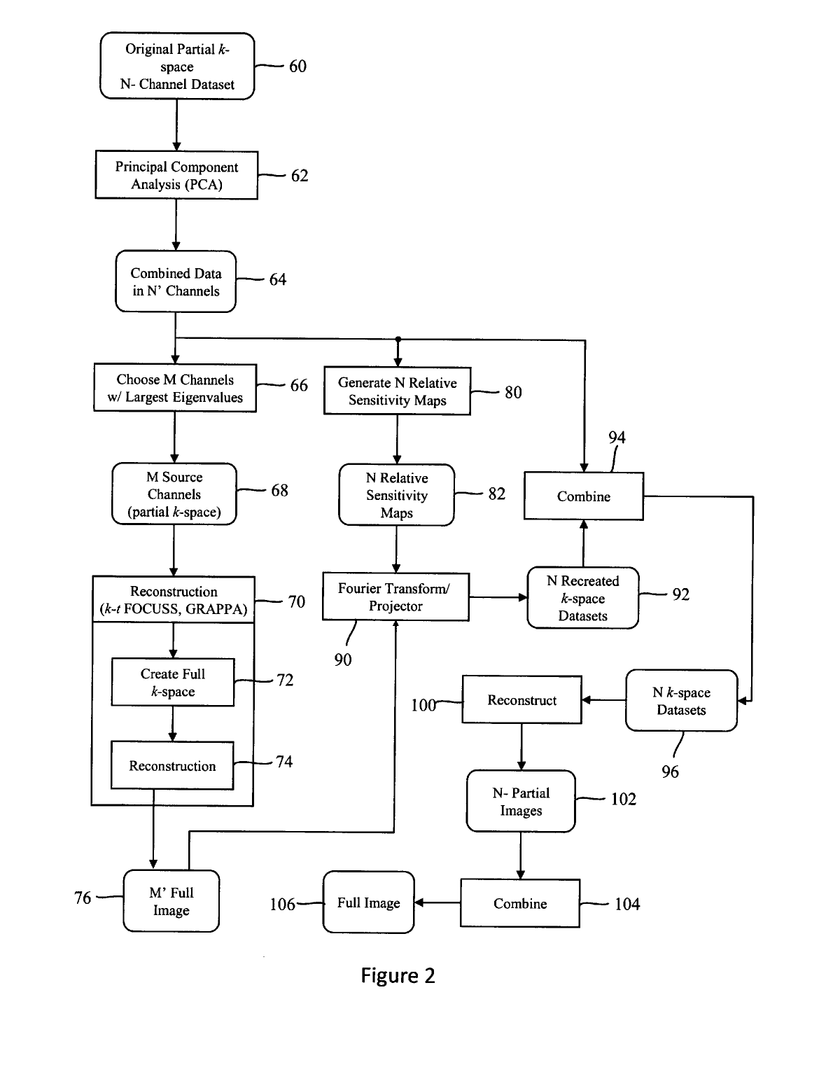

FIG. 2 is a flow chart detailing an image reconstruction process; and,

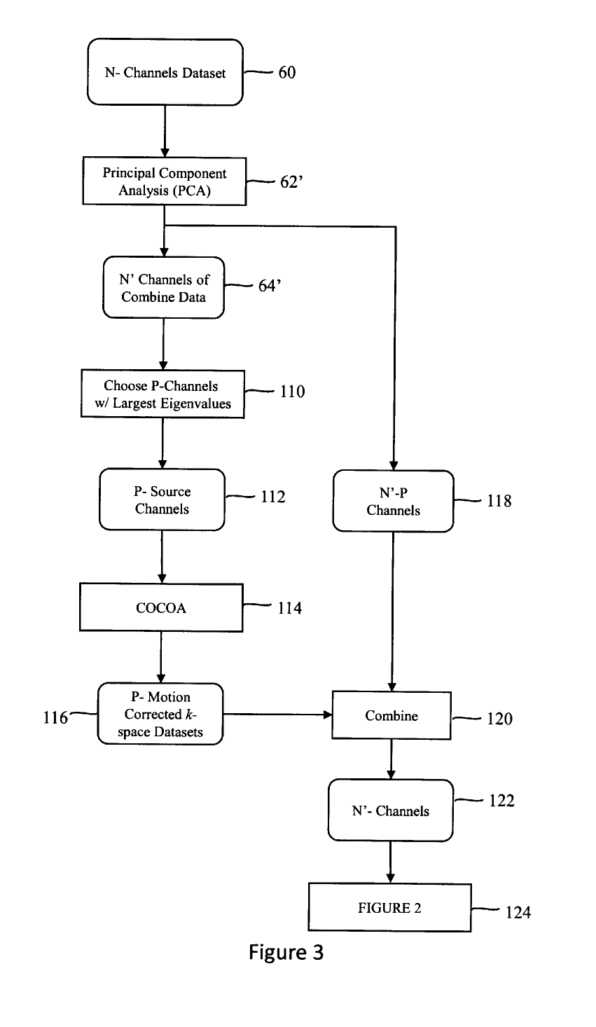

FIG. 3 is a flow chart illustrating a motion correction process.

With reference to FIG. 1, a magnetic resonance imaging system 10 includes a main magnet 12 which generates a temporally uniform B₀ field through an examination region 14. The main magnet can be an annular or bore-type magnet, a C-shaped open magnet, other designs of open magnets, or the like. Gradient magnetic field coils 16 disposed adjacent the main magnet serve to generate magnetic field gradients along selected axes relative to the B₀ magnetic field.

A radio-frequency (RF) coil array, such as a whole-body radio frequency coil, is disposed adjacent the examination region. The RF coil array includes a plurality of individual RF coil elements 18, or may be a birdcage-type coil with the multiple elements 18 interconnected by end ring RF coil structures. The RF coil array generates radio frequency pulses for exciting magnetic resonance in aligned dipoles of the subject. In some embodiments, the radio frequency coil assembly 18 also serves to detect magnetic resonance signals emanating from the imaging region. In other embodiments, local or surface RF coils 18′ are provided in addition to or instead of the whole-body RF coil for more sensitive, localized spatial encoding, excitation, and reception of magnetic resonance signals. The individual RF coils 18 together can act a single coil, as a plurality of independent coil elements, as an array such as in a parallel transmit system, or a combination.

A scan controller 20 controls a gradient controller 22 which causes the gradient coils to apply selected phase encode gradients across the imaging region, as may be appropriate to a selected magnetic resonance imaging or spectroscopy sequence. The scan controller 20 also controls an RF transmitter 24 which causes the whole-body or local

RF coils to generate magnetic resonance excitation and manipulation B₁ pulses. The scan controller also controls an RF receiver 26 which is connected to the RF coils 18, and/or a dedicated receive coil 18′ placed inside the examination region 14, to receive magnetic resonance signals therefrom. In a parallel system, the RF receiver 26 includes a plurality of receivers or a single receiver with a plurality of receive channels, each receive channel is operatively connected to at least one corresponding coil element 18 of the assembly. For example, 32 coil elements with 35 transmitters can provide 32 transmit channels and the 32 coil elements with 32 corresponding receivers can define 32 receive channels.

The received data from the receiver channels are temporarily stored in a data buffer 28 and processed by a magnetic resonance data processor 30. The magnetic resonance data processor can perform various functions as are known in the art, including image reconstruction, magnetic resonance spectroscopy processing, catheter or interventional instrument localization, and the like. Reconstructed magnetic resonance images, spectroscopy readouts, interventional instrument location information, and other processed MR data are displayed on a graphical user interface 32. The graphic user interface 32 also includes a user input device which a clinician can use for controlling the scan controller 20 to select scanning sequences and protocols, and the like.

Single channel, such as k-t FOCal Underdetermined System Solver (k-t FOCUSS), and channel-by-channel reconstruction techniques, such as Generalized Auto-calibrating Partially Parallel Acquisitions (GRAPPA), Data Convolution and Combination Operation (COCOA), Direct Virtual Coil (DVC), Synthetic Target (ST), parallel reconstruction Based on Successive Convolution Operations (BOSCO), or the like, have been developed to improve the speed of parallel imaging (PI) and partially parallel imaging (PPI) techniques. The techniques involve replacing the spatial encoding information, typically determined by the gradient controller 22 with the gradient coils 16, with spatial information contained in the RF coil array, e.g. characteristics of each coil element 18 such as position, orientation, size, and shape are incorporated into the received MR signals.

In partially parallel imaging techniques only a fraction of the phase encodes lines acquired compared to conventional parallel acquisitions. One of the mentioned reconstruction techniques is the applied to the acquired dataset to reconstruct the missing data, resulting in a full k-space dataset and thus a full FOV image. A problem with these PI and PPI reconstruction techniques and others is that as the number of RF receiver 26 channels increases so does the reconstruction time. In a single channel technique such as k-t FOCUSS the reconstruction time increases linearly with each channel count. For channel-by-channel techniques such as GRAPPA and COCOA, the reconstruction time increases quadratically. For example, a 32 channel coil array may take up to 16 times longer than an 8 channel coil array.

The magnetic resonance data processor 30 includes one or more processors which are programmed to perform the method described in conjunction with FIG. 2. More generally stated, the magnetic resonance data processor 30 includes a channel compression unit 40 which compresses or combines some or all of the receive channels to reduce the number of channels to be reconstructed, which reduces the processing time. However, images or the underlying data produced by the channel compression unit are typically subject to errors or artifacts. A relative sensitivity map generator 42 determines a relative sensitivity map indicative of the relative sensitivity of each of the receive channels. This can be facilitated by using the auto-calibration signal (ACS) which is typically generated with the sensitivity maps. For example, in some reconstruction techniques, the direct current or DC component can be used as a basis for generating the relative sensitivity maps. The relative sensitivity maps are used by a data correction/expansion unit 44 which uses the relative sensitivity maps to correct k-space or image space data from the channel compression unit to correct for the information lost in the compression process, e.g., by substituting original uncompressed data for missing data points. For example, the data correction/expansion unit can expand the reduced number of channels from the channel compression unit back to the original number of receive channels or at least a larger number of receive channels. A final reconstruction unit 46 reconstructs the corrected/expanded data into an image representation which is stored in an image memory 48.

With reference to FIG. 2, the original N channels of data, e.g., N=32, are received at 60 and are processed by a principle component analysis (PCA) unit, routine, or means to generate N′ channels, e.g., N′=24, of combined data 64. A unit, routine, or means 66, chooses a subset of the channels. For example, M channels are chosen which have the largest eigenvalues. For example, the original 32 channels can be reduced to 12 channels, 6 channels, and, in some embodiments, even to 1 channel. This results in M partial k-space source channels 68. The M partial k-space source channels can be considered as inputs from a virtual composite coil.

A k-t FOCUSS or GRAPPA or other partially parallel reconstruction technique is implemented by a multi-channel reconstruction unit, routine, or means 70. The parallel reconstruction unit, routine, or means 70 includes a unit, routine, or means 72 which combines, interpolates, and extrapolates the data from the M source channels to create a full k-space data set. The full k-space data set is reconstructed by a reconstruction unit, routine, or means 74, into M′ full images 76. M′ can be the same as M or, for a two-stage compression, M′ can be less than M. For example, 32 original receive channels can be compressed into 12 source channels and reconstructed into 8 channels or 8 images to reduce data processing time. For example, the number of k-space data lines and/or the number of data points in each k-space data line can be reduced to reduce the number of mathematical operations.

A calculation unit, routine, or means 80 generates relative sensitivity maps for the N′ combined data channels. The relative sensitivity maps can be calculated from sensitivity maps previously generated during setup for each coil element using a DC component of each sensitivity map as a reference point to determine the N relative sensitivity maps 82. In an alternate embodiment, N relative sensitivity maps are generated from the original N channels.

A Fourier-transform/projector unit, routine, or means 90 uses the N′ relative sensitivity maps to Fourier-transform of the M′ full images pointwise multiplied by each of the N′ relative sensitivity maps 82 to generate N′ recreated k-space data sets 92, corresponding to the N′ channels. A combining unit, routine, or means 94 combines each of the N′ combined data sets or channels with a corresponding one of the recreated N′ data sets. More specifically, in each of the recreated k-space data sets 92, data values which are actually available from the corresponding channel are substituted for the corresponding recreated data value. In some instances, the recreated k-space data sets may be missing. In this manner, N′ substituted full k-space data sets 96 are generated.

A reconstruction unit, routine, or means 100 reconstructs each of the N′ substituted k-space data sets to generate N′ partial images. An image combining unit, routine, or means 104 combines the N′ k-space images to generate a full image 106.

With reference to FIG. 3, if some of the k-space signals are motion-artifacted, the relative sensitivity maps may be artifacted as well. Accordingly, it is advantageous to use a motion-correction technique. The original N channel data 60 is processed with a principle component analysis unit, routine, or means 62 to generate N′ channels of combined data 64′. Alternately, the N′ combined channels are used as the starting point.

A unit, routine, or means 110 chooses P channels of the combined channels with the largest eigenvalues, i.e. the channels with the majority of the motion artifacts, to generate P source channels 112 with large eigenvalues. A COCOA unit, routine, or means 114 applies the data convolution or combination operation motion-compensation technique using channel-by-channel k-space convolution to generate P motion-corrected k-space data sets 116. In the meantime, the N′-P channels 118 with the smaller eigenvectors are less motion affected and have unreliable relative sensitivity maps, and therefore are not corrected for motion. A combining unit, routine, or means 120 combines the P motion-corrected channels 116 with the N′-P channels with the smaller eigenvectors to generate N′ channels 122. These combined channels with the lowest eigenvalues can be used directly in the final reconstruction (100) without extra processing (120)

A unit, routine, or means 124 performs the method of FIG. 2. The unit, routine, or means 124 performs a channel combination to compress most of the information into a few channels. One or a few of the compressed channels are used to produce a virtual coil, the number of combined channels being decided by the coil geometry and the region of interest. A channel-by-channel reconstruction algorithm is applied to the compressed channels one-by-one to compose the virtual coil. The reconstruction of these compressed channels is combined together to produce the virtual composite coil full image 76. The relative sensitivity maps 82 of the individual channels are calculated. The reconstruction of the virtual composite coil image 76 is Fourier-transformed and backprojected 90 into k-space for each individual channel to insert 94 all of the acquired data into the recreated k-space data sets 92. The final image 106 is the combination 104 of images 102 reconstructed from all channels.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A method for magnetic resonance imaging, comprising:
generating a first image representation of an examination region based on a plurality of partial k-space data sets, each data set being associated with at least one channel;
generating a relative sensitivity map for each of a plurality of coil elements, each coil element being associated with at least one channel;
projecting the first image representation and each relative sensitivity map to generate a plurality of recreated k-space data sets, each generated recreated k-space data set corresponding to one partial k-space dataset; and
combining each partial k-space data set and the corresponding recreated k-space data set to generate substituted k-space data sets.

2. The method according to claim 2, further including:
reconstructing each substitute k-space data set into a partial image representation of the examination region; and
combining the partial image representations into a volume representation.

3. The method according to claim 1, wherein the step of generating the first image representation includes:
compressing the plurality of partial data sets into at least one compressed partial data set;
reconstructing the at least one compressed partial data set the first image representation.

4. The method according to claim 3, wherein the plurality of partial data sets is compressed into the at least one partial data set based on a principal component analysis.

5. The method according to claim 3, wherein the plurality of partial data sets is compressed into more than one partial data set and the reconstruction is based on a channel-by-channel partially parallel imaging algorithm.

6. The method according to claim 1, wherein the relative sensitivity maps are calculated sensitivity maps for each coil element and from an auto-calibration signal generated during the reconstruction of the first image representation or a pre-scan to generate the sensitivity maps.

7. The method according to claim 1, wherein combining the partial k-space data sets and the recreated k-space data set includes substituting actually collected data from the partial k-space data sets for corresponding or missing data in the recreated data set.

8. The method according to claim 1, wherein generating the first image representation includes:
performing principle component analysis on the partial k-space data sets to generate combined partial k-space data sets;
selecting a subset of the combined partial k-space data sets with the largest eigenvalues;
reconstructing the subset of combined partial k-space data sets into the first image representation using a partial parallel image reconstruction technique.

9. The method according to claim 8, wherein the step of selecting a subset of combined partial k-space data sets with the largest eigenvalues, includes:
selecting a subset of the combined partial k-space data sets with the smallest eigenvalues; and
performing motion correction on the selected subset of combined partial k-space data sets with the largest eigenvalues; and
combining the motion corrected subset of combined partial k-space data sets with the subset of the combined partial k-space data sets with the smallest eigenvalues.

10. A magnetic resonance imaging system comprising:
a plurality of RF coil elements;
a plurality of RF transmitters;
a plurality of RF receivers each connected with one of the coil elements;
gradient magnetic field coils;
a gradient coil controller;
a magnetic resonance scan controller which controls the RF transmitters, the RF receivers, and the gradient controller to generate a plurality of partial k-space data sets, each data set being associated with a least one channel defined by a corresponding pair of RF coil elements and RF receiver; and
a computer processor programmed the method according to Claim 1.

11. A magnetic resonance imaging system comprising:
a plurality of coil elements and corresponding receivers which define a plurality of channels, data from the channels during the magnetic resonance imaging sequence constituting a plurality of k-space data sets;
one or more processors programmed to:
generate a first image representation of an examination region based on the plurality of k-space data sets,
generate a relative sensitivity map for each of the channels,
project the first image representation with each of the relative sensitivity maps to generate a corresponding plurality of recreated k-space data sets, and
combine each partial k-space data set and the corresponding recreated k-space data set to generate substituted k-space data sets.

12. The apparatus according to claim 11, further including:
reconstructing each substitute k-space data set into a partial image representation of the examination region; and
combining the partial image representations into a volume representation.

13. The apparatus according to claim 11, wherein the step of generating the first image representation includes:
compressing the plurality of partial data sets into at least one compressed partial data set;
reconstructing the at least one compressed partial data set into the first image representation.

14. The apparatus according to claim 13 wherein the plurality of partial data sets is compressed into the at least one partial data set based on a principal component analysis.

15. The apparatus according to claim 13, wherein the plurality of partial data sets is compressed into more than one partial data set and the reconstruction is based on a channel-by-channel partially parallel imaging algorithm.

16. The apparatus according to claim 11, wherein the relative sensitivity maps are calculated sensitivity maps for each coil element and from an auto-calibration signal generated during the reconstruction of the first image representation or a pre-scan to generate the sensitivity maps.

17. The apparatus according to claim 11, wherein combining the partial k-space data sets and the recreated k-space data set includes substituting actually collected data from the partial k-space data sets for corresponding or missing data in the recreated data set.

18. The apparatus according to claim 11, wherein generating the first image representation includes:
performing principle component analysis on the partial k-space data sets to generate combined partial k-space data sets;
selecting a subset of the combined partial k-space data sets with the largest eigenvalues;
reconstructing the subset of combined partial k-space data sets into the first image representation using a partial parallel image reconstruction technique.

19. The method according to claim 18, wherein the step selecting a subset of combined partial k-space data sets with the largest eigenvalues, includes:
selecting a subset of the combined partial k-space data sets with the smallest eigenvalues; and
performing motion correction on the selected subset of combined partial k-space data sets with the largest eigenvalues; and
combining the motion corrected subset of combined partial k-space data sets with the subset of the combined partial k-space data sets with the smallest eigenvalues.

20. In an image reconstruction system which generates a plurality of channels of partial k-space data, one or more processors programmed to:
compress the partial k-space data sets into a fewer number of channels;
generating a virtual coil image from one or more of the compressed channels;
applying a channel-by-channel reconstruction algorithm to the k-space data values of the compressed channels to generate a virtual coil image;
calculating a relative sensitivity map of the original channels;
projecting the virtual composite coil image using the relative sensitivity maps to generate a recreated sensitivity map corresponding to each original channel;
inserting acquired data from the partial k-space data sets into each of the corresponding recreated k-space data sets to generate substituted k-space data sets; and
reconstruct and combine the plurality of recreated k-space data sets.
